(19) United States
(12) Patent Application Publication
(10) Pub. No.: US 2024/0005709 A1
(43) Pub. Date: Jan. 4, 2024

(54) METHOD FOR TESTING A CONTROL DEVICE

(71) Applicant: Robert Bosch GmbH, Stuttgart (DE)

(72) Inventors: Rainer Baumgaertner, Pfaffenhofen (DE); Fred Zobel, Kornwestheim (DE); Reiner Motz, Freiberg (DE)

(21) Appl. No.: 18/340,125

(22) Filed: Jun. 23, 2023

(30) Foreign Application Priority Data
Jul. 4, 2022 (DE) 10 2022 206 821.1

(51) Int. Cl. G07C 5/08; G07C 5/00

(52) U.S. Cl. CPC G07C 5/0841; G07C 5/008

(57) ABSTRACT

A method for testing at least one control device. In the method, the at least one control device is switched multiple times using measurement technology that comprises a piece of measurement technology hardware and a piece of measurement technology software, and measurement data of the control device, in which the multiple switching operations can be identified, are recorded by the measurement technology so that the switching operations are automatically recognized.

### CROSS REFERENCE

The present application claims the benefit under 35 U.S.C. § 119 of German Patent Application No. DE 10 2022 206 821.1 filed on Jul. 4, 2022, which is expressly incorporated herein by reference in its entirety.

### FIELD

The present invention relates to a method for testing a control device, in particular a control device in a vehicle, and to an arrangement for carrying out the method.

### BACKGROUND INFORMATION

Control devices are electronic modules used for controlling processes and technical apparatus in an open- and closed-loop manner. Control devices are used in vehicles or motor vehicles, for instance, at various points and for various purposes. Together with other control devices, control devices are used in the vehicle electrical system of a motor vehicle and thus in a network.

German Patent Application No. DE 10 2018 209 407 A1 describes a method for handling an anomaly in a communication network in a motor vehicle, in which a detector analyzes a data stream in the communication network, the detector recognizing the anomaly using a rule-based anomaly recognition method if at least one parameter for a data packet of the data stream deviates from a target value.

Control devices are also used in connection with so-called driver assistance systems, which are auxiliary electronic equipment in motor vehicles for assisting the driver in certain driving situations. Currently, driver assistance systems for partially and highly automated driving are still in the development phase. In this respect, it should be noted that the complexity of the software used will be many times greater than in present-day automotive systems. Systems for automated driving are technically demanding, and this will also be the case with future robotics systems, which require lots of computing power and a large memory. In addition, these systems have to comply with considerably stricter safety requirements. Taking account of the functional safety requirements further increases the complexity of the system.

Central control devices form the execution platform for automated driving. In this case, one or more so-called single-chip modules or system-on-chip (SoC) modules are installed. An SoC is understood as a module or chip, i.e., an integrated circuit on a semiconductor substrate, in which all or many of the functions of an electronic system are integrated. Each of these SoCs internally consists of a plurality of arithmetic logic units. By way of example, the arithmetic logic units used include performance cores, safety cores, security cores, digital signal processors (DSPs), hardware accelerators, deep neural networks (DNNs), hardware video image conditioning, video processing, for example optical flow, filters, video structure recognition, and computer vision.

Since these arithmetic logic units are all integrated on a single chip, there are formidable challenges in terms of software development, analysis, enabling, and production software. In the process, the safety measures and the complex power-up operation of the control device and its individual arithmetic logic units make analysis more difficult.

One of the main analysis tools is measurement technology. By way of suitable interfaces, measurement technology externally delivers information related to the internal status of the software. Conclusions can then be drawn on the behavior on the basis of that information.

Present-day control devices distinguish between two software layers:

Basic Software (BSW)

This is the part of the software that operates the individual hardware components and hardware interfaces of the control device and/or arithmetic logic units. Since the BSW is therefore dependent on hardware, there is multi-layer dependence on external events that are difficult to measure.

Middleware-Centric Software

This is software that does not require direct hardware access and can thus run on a so-called middleware interface. In this case, data are merely consumed by the middleware and produced using the middleware. There are rarely any other influences, if at all. Middleware is understood as hardware and software that are used for data exchange between different hardware systems.

In addition, the measurement technology is subdivided further across different arithmetic logic units. For instance, present-day central control devices are based on one or more SoCs, each having one or more arithmetic logic units. This means that there may be one BSW measurement technology and one middleware measurement technology for each arithmetic logic unit and SoC. In addition, present-day systems consist of a plurality of control devices. The challenge here is measuring a plurality of control devices in the interconnected system.

Even in simple computer topologies, the power-up and power-down of a control device can only be analyzed to a very limited extent. In central control devices comprising a plurality of SoCs, each having a plurality of arithmetic logic units per SoC, the difficulties increase. Present-day measurement technology barely assists with the repeated switching on and off of a control device.

Robustness tests are required for the purpose of enabling, for example hardware in the loop (HIL) and customer trials in vehicles. In many cases, this necessitates hundreds if not trillions of power-up and power-down cycles, and the statistical evaluation of these cycles does not yield any guidance on further testing until the end. So far, traditional measurement technology has required manual interventions in order to make it through at least one power-down/power-up cycle, for example with a reset. Generally speaking, there is no assistance with the switching off of the control device power supply. As a result, if, for example, problematic situations do not occur until after cycles, for example, no results or findings as to what exactly caused the problem are obtained. Often, only the first cycle is measured.

To clarify some terminology:

Measurement technology should be understood as a concept that is based on hardware components and implemented in most control devices nowadays. In the process, one or more arithmetic logic units are measured.

Present-day computers are generally so-called chips, for example made of silicon. A chip may contain a single computer unit or a plurality of computer units. SoCs are special chips that contain a complex array of computer units and the infrastructure needed for the computer units to be able to work together.

In addition, there is an external infrastructure, the measurement technology itself, which records the measurement data, for example software variables, middleware messages, and events, for example in a memory having several gigabytes of storage. These memories are, for example, mass memories such as hard disks, solid state drives (SSDs), secure digital memory cards (SDs), embedded multimedia cards (eMMCs), and RAIDS (redundant arrays of independent disks). By using, for example, a provided piece of external measurement technology software on the arithmetic logic unit, for example a personal computer (PC), analysis can be performed in real time or offline. The external measurement technology software may also have a piece of measurement technology hardware for capturing the vast data rates. In this case, the measurement technology hardware can also be further subdivided, for example into a component at control device level, which is located in or on the control device, and a measurement technology hardware component that is external to the control device and connected to the component at control device level by a suitable interface.

It is thus possible to record some of the data flow concurrently with the actual function. In this case, the acquired data are led out of the arithmetic logic units and out of the computer or chip via a suitable hardware interface. In most cases in SoCs these are one or more PCIe interfaces, dual-port interfaces, bus interfaces, optical fiber interfaces, measurement technology interfaces, communication interfaces, e.g., Ethernet serial interfaces, controller area networks (CAN), and Flexray, which are run on one or more separate hardware interfaces.

Likewise, logging can be used to attempt to access UART (serial interface), Ethernet, etc. However, only a fraction of the problems can be identified in this case. In addition, either additional computing power is constantly needed or the software has to be modified. Doing so requires an extremely large amount of analysis work and in many cases is not expedient as modifying the software often also modifies the behavior.

In many cases, the data that are to be measured, for example in endurance tests which may last weeks or months, cannot be modified retrospectively either since the endurance test has to be carried out again.

### SUMMARY

According to the present invention, a method and an arrangement are provided. Specific embodiments of the present invention are disclosed herein.

A method according to the present invention is used for testing at least one control device. According to an example embodiment of the present invention, in the method, the at least one control device is switched multiple times using measurement technology that comprises a piece of measurement technology hardware and a piece of measurement technology software, and measurement data of the control device, in which the multiple switching operations can be identified, are recorded by the measurement technology. In this way, switching operations can be recognized automatically, i.e., without any user action.

In one embodiment of the present invention, all the data from the switching operations are stored. In addition, the method can be carried out without influencing the software running on the at least one control device.

The at least one control device can be powered up and/or powered down at least once during the test. Likewise, the measurement can be automatically initiated again with the next power-up.

Herein, “switching” should be understood as switching on and/or off, i.e., powering up or powering down. In motor vehicles, this is, for example, an SoC reset, an on/off ignition, or a delayed switch-off of the control device via the network management, as well as the disconnection of the control device from the vehicle electrical system voltage and voltage fluctuations on the vehicle electrical system.

Thus, a method is provided according to an example embodiment of the present invention in which the measurement technology software and the measurement technology hardware are expanded such that a measurement technology operation can also be carried out using one or more switch-on or switch-off operations or power-up and power-down operations, i.e., reset or power-off/power-on. The method can, for example, be used in conjunction with SoCs and central control devices but is basically suitable for any type of hardware that is to be measured using measurement technology.

Thus, even interconnected systems of a plurality of control devices can be measured when switched on or powered on. Power-on measurement can be handled separately per control device, and the acquired data can be compiled at a later time.

In addition, the power-on measurement can be carried out jointly for a plurality of control devices; in this case, account must be taken of the different power-up or start-up behaviors of the individual control devices.

Moreover, the power-on measurement can be carried out jointly and in a synchronized manner for a plurality of control devices, in which case the powering up of a plurality of control devices should also be synchronized.

One aim here is for the measurement technology data from the control device to be automatically logged over one or more power-up operations.

The individual power-up operations can then be unambiguously identified in the measurement data.

According to an example embodiment of the present invention, It is also expedient for the above-described method to function using control devices that contain a plurality of computers/chips, e.g., SoCs, the individual computers being measurable by way of a plurality of power-up or initiation operations.

All possible communication interfaces present in the control devices are potential interfaces between the control device and the external measurement technology hardware and software.

The individual measurement technology implementations based thereon differ on account of the achievable bandwidth, the influence of the software, for example the computing power demand additionally required in the control device and/or the additionally required memory capacity, and the time from when measurements can be taken.

Possible measurement technology interfaces are:
1. CAN,
2. Flexray,
3. LIN,
4. Ethernet,
5. SPI,
6. UART,
7. PCIe,
8. high-speed serial interfaces, e.g., video interfaces,
9. debug interfaces, e.g., JTAG, NEXUS, trace interfaces, e.g., proprietary trace ports, HSSTP, ETR, PCIe, AURORA, dual-port interfaces.

A trace interface is a hardware property of the SoC that enables high-bandwidth debugging. In this case, no action is required from the software. The trace hardware transparently reads the data from the SoCs, without the SoC taking notice thereof, and relays the data to a hardware interface.

A combination of a plurality of interfaces 1 to 10 can also be used. Examples:
a. Interface 9 for setting up the measurement, with the measurement then to be carried out using interface 10.
b. One of interfaces 1 to 9 for setting up the measurement, with the measurement then to be carried out using one or more of interfaces 1 to 10.

An embodiment of the present invention in which measurements are carried out using one or more power-up operations is possible for all these types of interface.

Interfaces 1 to 8 can be driven solely from the control device side. In this case, the external measurement technology software and/or hardware should merely be able to log the data when they are sent by a control device. Here, it is expedient if the individual power-up operations are unambiguously identified in the measurement data by way of suitable signals. In general, the drawback of this specific embodiment is that computing power is additionally permanently required and/or that additional memory usage is needed on the control devices.

In interfaces 1 to 10, it is also expedient or necessary for the measurement technology operation to be initiated or co-initiated externally; this is essential in interfaces 9 and 10, for example. In this case, it then also has to be ensured that the power-up behavior of the control device is influenced as little as possible. If the power-up behavior is influenced by the measurement operation, then the behavior acquired by the measurement may not match the normal behavior of the control device, as a result of which the measurement technology becomes considerably less meaningful.

Generally speaking, in specific embodiments based on interface 10, it is expedient for less permanently required computing power and/or less additional memory on the control devices to be needed. In this regard, it is also expedient for the software to be the least influenced as it is generally executed on additional SoC trace hardware. SoC trace hardware is additional hardware mechanisms that forward information related to the program cycle and/or the data being used to a suitable hardware interface without any action from the software.

Further advantages and embodiments of the present invention become apparent from the description herein and the figures.

It goes without saying that the features described above and hereinafter can be used not only in the combination stated, but also in other combinations or in isolation, without departing from the scope of the present invention.

### BRIEF DESCRIPTION OF THE DRAWINGS

FIG. 1 is a block diagram of a control device in an environment for carrying out a specific embodiment of the method being presented, according to the present invention.

FIG. 2 is a flowchart of a possible sequence of the method according to an example embodiment of the present invention being presented.

### DETAILED DESCRIPTION OF EXAMPLE EMBODIMENT

The present invention is illustrated schematically in the figures on the basis of specific embodiments and will be described in detail below with reference to the figures.

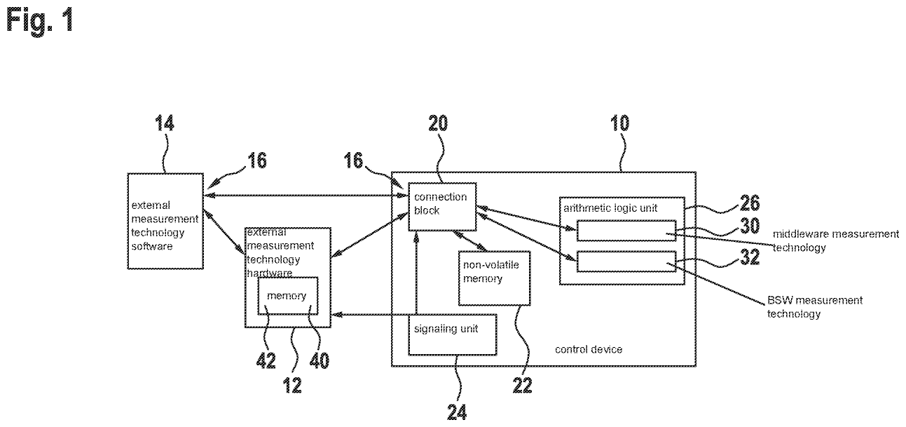

FIG. 1 is a schematic illustration of a control device (denoted in general by reference numeral 10) in an environment for carrying out a possible specific embodiment of the method being described.

The illustration shows a control device 10, an optional piece of external measurement technology hardware 12, and a piece of external measurement technology software 14, which is saved on a PC, for example. One or more measurement technology interfaces are denoted by reference numeral 16.

One or more connection blocks 20, an optional non-volatile memory 22 for the status “Power-on measurement underway,” an optional unit 24 for signaling “Power control devices up/down,” and one or more arithmetic logic units 26 are provided in the control device 10. Middleware measurement technology 30 and BSW measurement technology 32 are provided in said arithmetic logic units.

An optional external measurement technology memory 40 is saved in the optional external measurement technology hardware 12. An optional measurement technology memory 42 is provided in the external measurement technology software 14.

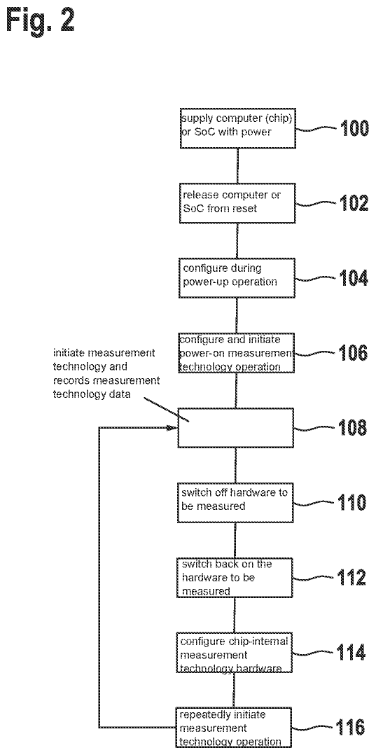

FIG. 2 is a flowchart of a sequence of an example method of the type described herein. The described steps need not be carried out successively in the stated order.

In a first step 100, the computer (chip) or SoC is supplied with power.

In a second step 102, the computer or SoC is released from the reset. Thus begins the power-up operation. A plurality of arithmetic logic units are installed inside an SoC. Upon primary initiation, preferably a subset of the arithmetic logic units is initiated, e.g., a primary arithmetic logic unit which then initiates the next arithmetic logic units, and so on. The method being described can or should be applied successively to all the arithmetic logic units to be measured. In some cases, it may be that only a subset of the arithmetic logic units can be measured simultaneously, for example to limit the bandwidth at the measurement technology interface. If the bandwidth is large enough, it is advantageous to measure everything.

In a further step 104, the following can be configured during the power-up operation for the arithmetic logic unit(s) to be measured:
i. the external measurement technology software via the measurement technology interface or the external measurement technology hardware and then, via the measurement technology interface, the externally configurable parts of the measurement technology interfaces,
ii. the control device software of the measurement technology interface,
iii. a combination of i. and ii.

In a further step 106 either therebefore or thereafter, the power-on measurement technology operation is configured and initiated, for example by the user by way of the measurement technology software. By way of example, the status “Power-on measurement underway” and, for example, the measurement parameters can be saved in the control device in a non-volatile memory. When next powered up, the control device can then automatically resume outputting measurement data.

In a further step 108, the measurement technology is initiated and records measurement technology data of the individual arithmetic logic units and one or more measurement technology layers, i.e., BSW-centrically and/or middleware-centrically.
i. Via the chip-internal logic and the measurement technology interface itself, the measurement technology data of the arithmetic logic unit being tested can be sent to the external measurement technology hardware and/or, expediently, to the measurement technology software and recorded. This is done, for example, in a circulating buffer and/or on mass memories.
ii. The measurement technology data of the arithmetic logic unit being tested can be compiled by the software in the control device and sent, via the measurement technology interface, to the external measurement technology hardware and/or, expediently, to the measurement technology software and recorded. This is done, for example, in a circulating buffer and/or on mass memories.
iii. Expediently, the measurement technology data of the arithmetic logic unit being tested are compiled by the external measurement technology hardware and, via the measurement technology interface, fetched and, for example, sent to the measurement technology software and recorded. Expediently, this is done in a circulating buffer and/or on mass memories.
iv. A combination of i. to iii.

If, in a further step 110, the hardware to be measured, e.g., the control device, is now switched off during operation, this is recognized in this embodiment by the external measurement technology hardware and/or the measurement technology software by:
i. individual signal pins led from the hardware to be measured to the external measurement technology hardware. By way of example, the reset output, the Power-Good output, or specific signals are suitable for this purpose,
ii. the continuous reading of the measurement technology data stream coming from the control device,
   I. By recognizing patterns in the measurement technology data stream, for example. One or more counters in the data stream can be set to zero. Status messages in the data stream that signal the power-up can be recognized.
iii. a signal via one of the communication interfaces of the control device, for example,
iv. continuously querying the status via the measurement technology interface, for example,
   I. No more communication is possible while the hardware to be measured is switched off. By way of example, the switching-off operation can be recognized by means of a timeout.
v. a combination of i. to iv.

If, in a step 112, the hardware to be measured, e.g., the control device, is switched back on, this is recognized, for example, by the external measurement technology hardware and/or the measurement technology software by:
i. individual signal pins led from the hardware to be measured to the external measurement technology hardware. By way of example, the reset output, the Power-Good output, or specific signals are suitable for this purpose,
ii. the continuous reading of the measurement technology data stream coming from the control device,
   I. By recognizing patterns in the measurement technology data stream, for example. One or more counters in the data stream can be set to zero. By way of example, status messages in the data stream that signal the power-up can be recognized.
iii. a signal via one of the communication interfaces of the control device, for example,
iv. continuously querying the status via the measurement technology interface, for example,
   a. No more communication is possible while the hardware to be measured is switched off. By way of example, the switching-off operation can be recognized by means of a timeout.
v. a combination of i. to iv.

A Power-Good output outputs a signal indicating that the SoC supply voltage is in the valid range. Particularly during switch-on and switch-off, the operating state, i.e., powered or not powered, can thus be recognized.

If, in a further step 114, the external measurement technology hardware and/or, expediently, the measurement technology software recognizes that the chip has been powered up again, it is also possible that only the measurement technology hardware does so; then, for example during the power-up operation of the arithmetic logic unit(s) to be measured, the external measurement technology software and/or measurement technology hardware configures the chip-internal measurement technology hardware belonging to the arithmetic logic unit via the external measurement technology hardware components and via a JTAG interface.

In this case (step 116), the measurement technology operation should not or cannot be initiated by the user of the measurement technology software since this has to be done thousands of times and/or the available time may be very short, for example a few milliseconds, for example in a cranking test. Expediently, the repeated measurement technology operation should be initiated automatically by the measurement technology hardware/software and/or by previously stored information in the control device, for example the information “Power-on measurement underway” and, for example, the measurement technology configuration stored in the control device. The configuration for this purpose was described above in steps 104 and 106.

From this time onward, the sequence repeats from step 108.

Typically, the measurement technology operation is continued until one or more events occur.
a) One or more values of measurement data and/or preferably the combination and sequence of measurement data can be used for bringing about termination.
b) Since the aim of the measurement in many cases is statistical inquiries, the end of the test can also terminate the measurement technology operation. Expediently, this is the end of the underlying test drive and/or test cycle and/or part of a test cycle.
c) The measurement can be terminated by the user.
d) The measurement can be terminated by a maximum file size being reached.

Once the measurement technology operation has ended, the user, for example, analyzes the acquired measurement technology data using the external measurement technology software, automated and/or partially automated analysis methods expediently also being able to be used.

What is claimed is:

1. A method for testing at least one control device, the method comprising the following steps:
switching the at least one control device multiple times using measurement technology that includes a piece of measurement technology hardware and a piece of measurement technology software; and
recording measurement data of the control device, in which the multiple switching operations can be identified, by the measurement technology so that the switching operations are automatically recognized.

2. The method as recited in claim 1, in which all data from the switching operations are stored.

3. The method as recited in claim 1, wherein the method is carried out without influencing software running on the at least one control device.

4. The method as recited in claim 1, wherein the at least one control device is powered up at least once during the testing.

5. The method as recited in claim 1, wherein the at least one control device is powered down at least once during the testing.

6. The method as recited in claim 5, wherein measuring is automatically initiated again with a next power-up.

7. The method as recited in claim 1, wherein a communication interface in the at least one control device is used as an interface between the at least one control device and the measurement technology.

8. The method as recited in claim 1, wherein the measurement data are analyzed in a final step once the testing has ended.

9. The method as recited in claim 1, wherein the method is terminated when an event occurs selected from a group consisting of the following: a particular measured value is obtained, a sequence of measured values is obtained, a combination of measured values is obtained, a test drive is ended, a user terminates the method, a maximum file size is reached.

10. The method as recited in claim 1, wherein an interconnected system of control devices is tested.

11. An arrangement for testing a control device, comprising:
measurement technology that includes a piece of measurement technology hardware and a piece of measurement technology software, wherein the arrangement is configured to:
switch the control device multiple times using the measurement technology, and
record measurement data of the control device, in which the multiple switching operations can be identified, by the measurement technology so that the switching operations are automatically recognized.

12. The arrangement as recited in claim 11, wherein the measurement technology is assigned at least one measurement technology memory.
